(19) United States
(12) Patent Application Publication
(10) Pub. No.: US 2013/0298959 A1
(43) Pub. Date: Nov. 14, 2013

(54) SHADE-TOLERANT THIN FILM PHOTOVOLTAIC PANEL

(71) Applicants: Muhammed A. Alam, West Lafayette, IN (US); Sourabh Dongaonkar, West Lafayette, IN (US)

(72) Inventors: Muhammed A. Alam, West Lafayette, IN (US); Sourabh Dongaonkar, West Lafayette, IN (US)

(21) Appl. No.: 13/790,415

(22) Filed: Mar. 8, 2013

Related U.S. Application Data
(60) Provisional application No. 61/644,653, filed on May 9, 2012.

(51) Int. Cl. H01L 31/0352; H01L 27/142; H01L 31/0224

(52) U.S. Cl. CPC H01L 31/035281; H01L 31/022425; H01L 27/1426
USPC 136/244

(57) ABSTRACT

A thin film photovoltaic panel includes a first plurality of photovoltaic cells electrically connected in series and arranged in a radial pattern. Another thin film photovoltaic panel has a first plurality of photovoltaic cells electrically connected in series. Each of the cells produces a respective current substantially equal to a selected first chain current under a selected illumination condition. The cells are shaped and arranged so that any straight-edged shadow falling on the panel at least partly shades two cells.

### CROSS-REFERENCE TO RELATED APPLICATIONS

This application is a nonprovisional of U.S. Patent Application Ser. No. 61/644,653, filed May 9, 2012 and entitled “A Shade Tolerant Panel Design for Thin Film Photovoltaics,” the entirety of which is incorporated herein by reference.

### FIELD OF THE INVENTION

The present application relates to photovoltaic panels, and particularly to such panels having photovoltaic elements (“cells”) separated by scribe lines.

### BACKGROUND OF THE INVENTION

Photovoltaic (PV) cells generate an electric current when exposed to light (a photocurrent). Thin-film photovoltaic (TFPV or, herein, simply “PV”) panels (or “modules”) include PV cells and are commonly used to produce electricity from solar or other illumination. An exemplary PV panel includes a stack of a substrate, a transparent electrode layer on the substrate, a p-i-n semiconductor diode layer, and an opaque (e.g., reflective) electrode layer. Since conventional PV photodiodes develop relatively low voltages under illumination, the layers are divided, e.g., by laser scribing. Rather than the single panel being a single, large-area photodiode (very high current; very low voltage), areas of the diode layer (“cells”) are separated from each other and connected in series by the conductive layers to form multiple spatially-separated area photodiodes (medium to high current; high voltage). For example, dividing a panel into ten series-connected cells would reduce the current to approximately 10% but increase the voltage by 10×.

Although a PV cell produces current when exposed to light, when shadowed or shaded, it behaves as a diode. When a PV cell is described herein as being in a shadowed or shaded state, it means that it is not receiving sufficient light of the relevant wavelength or wavelengths to produce substantially the photocurrent produced by other cells in series with it. If the illumination is reduced equally to the whole panel, it is not considered “shaded” as described herein, since no current mismatch between cells is induced (e.g., normal day-night cycling). Since the PV cells are arranged in series, when a portion of the series or string of cells is shadowed, the shadowed cell (or cells) acts as a diode in reverse bias to the remainder of the series or string. The remaining cells force current through this diode. As a result, the cell (or cells) acting as a diode in reverse bias tends to heat as it dissipates power, which can permanently damage that cell and potentially damage nearby cells. Partial shading that produces only a a moderate reverse bias in the shaded cells can reduce panel efficiency over the long term. Partial shading that produces a large enough reverse bias will cause the reverse-biased diode to break down, resulting in permanent damage (e.g., melting or burning) in the region of the cell where breakdown occurs. Breakdown can also require the panel to be replaced. Even if breakdown does not occur, the energy consumed in heating the cell is wasted, thus reducing the output power of the device. There is a need for ways of avoiding these negative effects.

Some prior schemes attempt to avoid damage using extra components. For example, U.S. Publication No. 2010/0147353 by Kamath describes a photovoltaic cell with an integrated shunt protection diode. The shunt protection diode is intended to protect non-generating (e.g., underilluminated) cells from excessive reverse bias. However, these diodes are formed directly on the PV substrate. As a result, each protection diode is an area of the panel in which electricity is not generated. This is undesirable, since efficiency of a panel or cell (watts of electricity out per watt of radiant flux in) is a function of the area available for generating power. U.S. Pat. No. 6,690,041 to Armstrong et al. describes monolithically integrated bypass diodes with similar drawbacks. U.S. Pat. No. 6,288,323 to Hayashi et al. also describes various arrangements of bypass diodes that require space on the panel, or additional manufacturing steps.

Other prior schemes attempt to avoid damage by conditioning the panel. Hayashi '323 also describes a scheme involving reverse-biasing cells of a manufactured panel under controlled conditions. Over time, the cells' ampacity for a given reverse-bias voltage increases, reducing the probability that an overcurrent will cause breakdown or damage. However, this method requires potentially time-consuming treatment of each manufactured panel. There is a continuing need, therefore, for improved resistance to damage of underilluminated cells.

### BRIEF DESCRIPTION OF THE INVENTION

Prior efforts to reduce detrimental effects on shaded panels do not even consider cell geometry. Instead, they attempt to improve the performance of a panel with conventional cells, such as those shown in FIGS. 1A and 1B. FIG. 1A is a schematic of solar power unit 90 including a plurality of solar panels 100 arranged in series. Each panel 100 has an associated protection diode 95. Inverter 96 converts high-voltage DC from the panels 100 to AC. Any number of panels, e.g., 1, >1, or 6, can be included in unit 90.

FIG. 1B is a plan view of conventional solar panel 100 (FIG. 1A), W_{module} wide and L_{module} long. Cells 105 are arranged in series, as described above (not all cells are labeled). Each cell 105 is rectangular in shape, and each cell 105 has the same shape. Panel 100 as a whole is also rectangular. Solar panels are often installed near buildings or other solar panels, both of which generally have straight edges that cast straight-edged shadows. Shadow 99 (dotted outline) is an example of a rectangular shadow falling on panel 100. Shadow 99 has width Wₛₕ along the cells and length Lₛₕ in the direction of current flow.

FIG. 2 shows an example of deleterious effects of shadows on panel 100. Cell 205 is entirely shaded by shadow 299 (dotted outline), but no other cell 105 is shaded. As a result, the current from the thirteen unshaded cells 105 is forced through the single reverse-biased cell 205. This can cause damage to cell 205. Since only one cell is shaded, the overall voltage between positive electrode 207 and negative electrode 201 is positive. Therefore, corresponding protection diode 95 (FIG. 1A) is in reverse cutoff and does not take any of the reverse bias off shaded cell 205. In some panel configurations, protection diode 95 only turns on when about half of the cells 105, 205 are shaded (e.g., eight cells out of 14). Protection diode 95 therefore cannot prevent shadow damage when only a small number of cells are shaded.

FIG. 3A shows results of a simulation of cell voltages, and FIG. 3B a simulation of panel power. Legends are shown above each figure. These simulations were performed in SPICE for a conventional a-Si:H panel 128 cm×128 cm, with 128 cells in series. Six panels connected in series were simulated, resulting in a string output of 535V DC at the maximum power point of each individual panel. Shown are the results of simulations when one of the panels is partially shaded, and evaluate the worst-case voltage developed across the individual cells of the shaded panel. Each cell was modeled as two current sources: one for any shaded area of the cell and one for any nonshaded area. The cell models were connected in series to form a one-dimensional equivalent circuit for simulation.

FIG. 3A shows the worst case reverse stress cell voltage for each cell simulated, and FIG. 3B shows the power output of the string of six panels, for shadow sizes from no shadow to one full panel shaded. FIG. 3B shows that power loss generally goes as area shaded. FIG. 3B, however, shows that reverse bias very specifically goes as increasing width and decreasing length (lower-right section of the plot). Moreover, an external bypass diode was simulated, but it only turned on for a fraction of shading scenarios, and did not prevent the worst case reverse stress. This is because, when Wₛₕ>>Lₛₕ, the fully illuminated cells continue to drive the current through the shaded cells, and push them in reverse bias. When a large number of cells are shaded (Wₛₕ>Lₛₕ), the stress on individual cells is reduced as the voltage is divided among the shaded cells. As the number of cells shaded decreases (L shrinks), the stress on each individual cell increases.

This dependence of reverse-bias cell voltage on shadow shape, not just shadow presence, is a previously unrecognized problem in the art. Prior schemes do not take this dependence into account, and so do not provide the advantages described herein. In view of the recognition of this problem, there is a newly-recognized need for a panel configured so that its cells are robust against variations in shadow shape.

The SONELIS company manufactures solar panels cut to particular shapes. However, only the perimeters of the panels are shaped, not the cells themselves. Accordingly, these panels do not provide the desired robustness in view of shadow shape.

According to an aspect of the invention, therefore, there is provided a thin film photovoltaic panel comprising a first plurality of photovoltaic cells electrically connected in series and arranged in a radial pattern.

According to another aspect of the invention, there is provided a thin film photovoltaic panel comprising a first plurality of photovoltaic cells electrically connected in series, each of the cells adapted to produce a respective current substantially equal to a selected first chain current under a selected illumination condition, wherein the cells are shaped and arranged so that any straight-edged shadow falling on the panel at least partly shades two cells.

Various aspects advantageously provide solar panels that have reduced susceptibility to power loss or damage induced by differential shading. Various aspects can be manufactured using standard laser scribing techniques. Various aspects have substantially the same electrical output (voltage and current) as conventional designs and so can be used as drop-in replacements for those designs.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1A is a schematic of a solar power unit;

FIG. 1B is a plan view of an exemplary thin-film photovoltaic (TFPV) panel that is partly shaded;

FIG. 2 is a representation of a shadow falling on a TFPV panel;

FIGS. 3A and 3B show simulation results of shadows falling on TFPV panels;

FIG. 4 is a perspective and cross-section of an exemplary TFPV panel;

FIG. 5 is a schematic of cells (one shaded, one not) in an exemplary TFPV panel;

FIG. 6 is a plan view of a TFPV panel according to various aspects;

FIGS. 7A-7D show simulation results of shadows falling on TFPV panels;

FIGS. 8A-8B show results of simulations of a radially-symmetric triangular-cell panel;

FIG. 9 is a plan view of a TFPV panel according to various aspects;

FIGS. 10A-10C shows results of simulations of resistive power dissipation in cells of various shapes, and FIG. 10D shows a common legend for FIGS. 10A-10C;

FIGS. 11A and 11B show results of simulations of a panel according to various aspects;

FIG. 12 is a plan view of a TFPV panel according to various aspects; and

FIGS. 13A-13D show steps in a process of designing a spiral cell shape.

The attached drawings are for purposes of illustration and are not necessarily to scale.

### DETAILED DESCRIPTION OF THE INVENTION

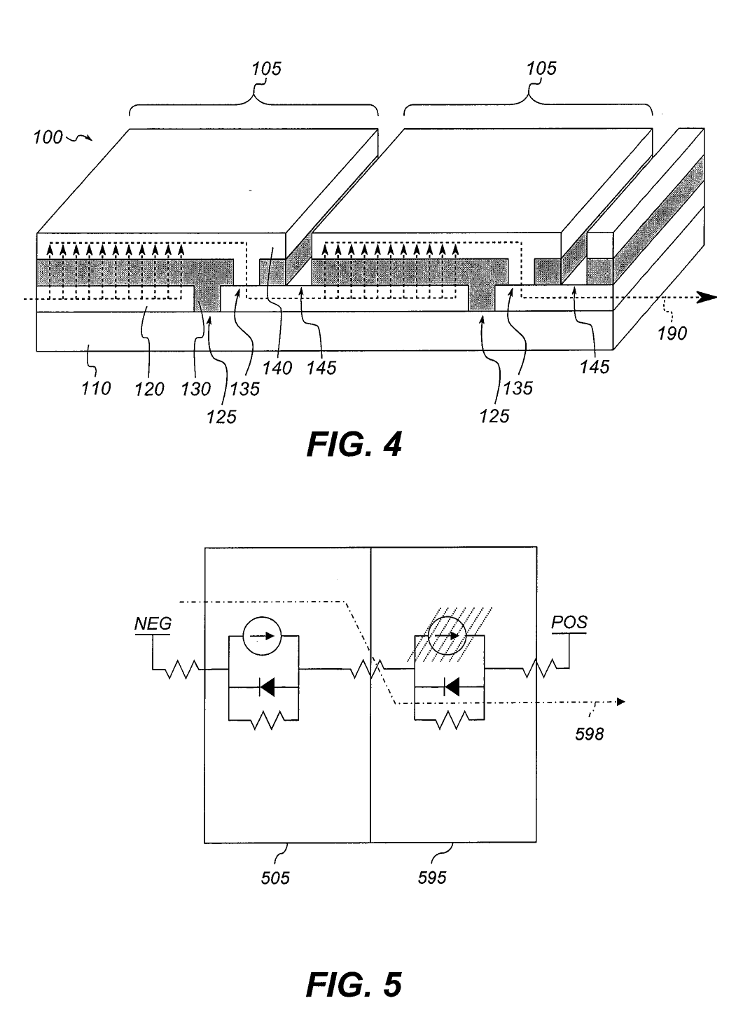

FIG. 4 is a perspective and cross-section of exemplary thin-film photovoltaic (TFPV) panel 100 having PV cells 105 electrically connected in series. Conductive layers 120, 140 are spaced apart (except at contacts, as noted below) by photovoltaic layer 130, all of which are disposed over substrate 110. Layers 120, 130, 140 have been scribed (e.g., divided by cutting along a path) to form a series-connected structure in which current flows, e.g., as indicated by current path 190. Conductive layer 120 has been scribed along scribe lines 125, PV layer 130 has been scribed along scribe lines 135, and both PV layer 130 and conductive layer 140 have been scribed along scribe lines 145.

Scribing can be performed by laser-cutting, physical scribing (scratching), and plasma etching can also be used. Substrate 110 can be glass, plastic, or metal, and can be rigid or flexible. PV layer 130 includes one or more layer(s) or material(s) that together form a junction at which the photovoltaic effect is exhibited. In an example, PV layer 130 includes two layers forming a P-N junction, or three layers forming a p-i-n diode structure. Each conductive layer 120, 140 can be transparent or translucent, and one of the conductive layers 120, 140 can be opaque, e.g., reflective. Conductive layers 120, 140 can include metals or oxides, including transparent oxides, e.g., ITO (indium tin oxide). In various aspects, panel 100 is produced by successive deposition and scribing steps: deposit 120, scribe 125, deposit 130, scribe 135, deposit 140, scribe 145.

Scribe lines 125 isolate conductive layer 120 in each cell 105 from conductive layer 120 in adjacent cells. Similarly, scribe lines 145 isolate conductive layer 140 in each cell 105 from conductive layer 140 in adjacent cells. Scribe line 135 serves as a contact; at scribe line 135, conductive layer 140 of one cell 105 connects to conductive layer 120 of an adjacent cell 105.

For example, a laser conventionally referred to as “P1” can be fired through glass substrate 110 to form scribe line 125. A “P2” laser can be fired through glass 110 to form scribe line 135. A “P3” laser can be fired through glass 110 to form scribe line 145. Laser P3 provides electrical isolation of PV cells next to each other. A TFPV module (panel) can be from 1-2 m² in area, with ˜100 cells in series, so that that each cell is approximately 1 cm by approximately 1 m in areal extent.

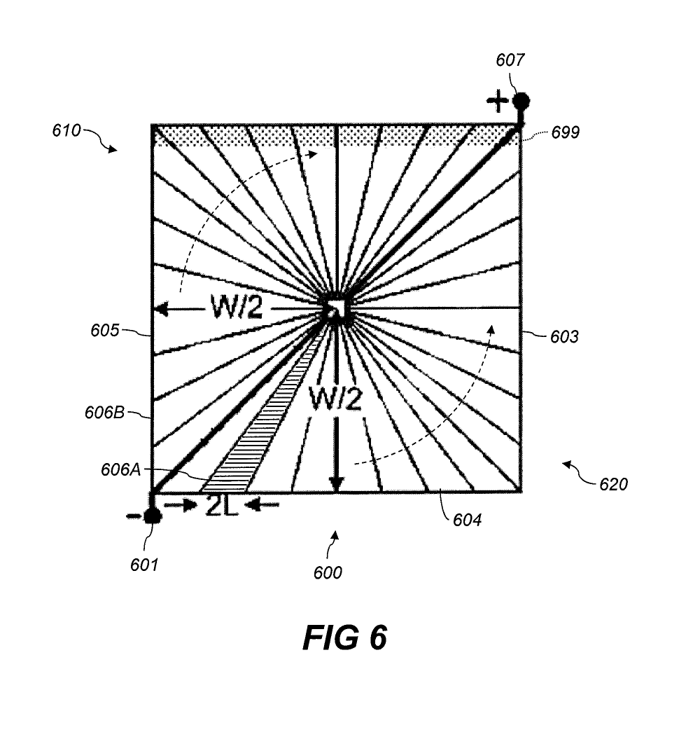

FIG. 5 is a schematic of cells 505, 595 in an exemplary TFPV panel. Cell 505 is not shaded, but cell 595 is shaded. The layer structure in each cell has electrical characteristics represented by an equivalent circuit. A portion of the equivalent circuit is shown here.

Current source 501 in cell 505 drives current from the NEG terminal towards the POS terminal, i.e., generates electrical power from incident photons. Diode 502 is forward biased. Diode 502 and resistor 503 model internal losses in cell 505.

In shaded cell 595, current source 591 does not supply current (in this example). Accordingly, the current being driven by source 501 passes through diode 592 and resistor 593, as shown by current path 598. When the voltage across resistor 593 exceeds the reverse breakdown voltage of diode 592, diode 592 begins to operate in reverse bias. As discussed above, this is undesirable.

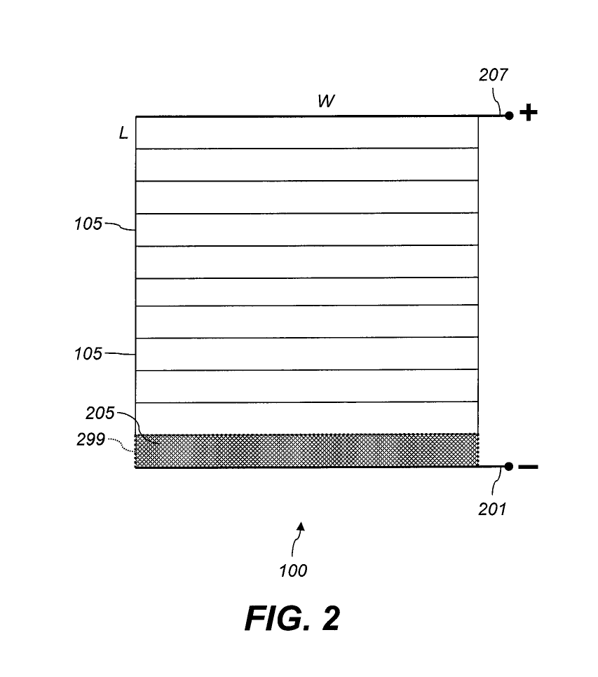

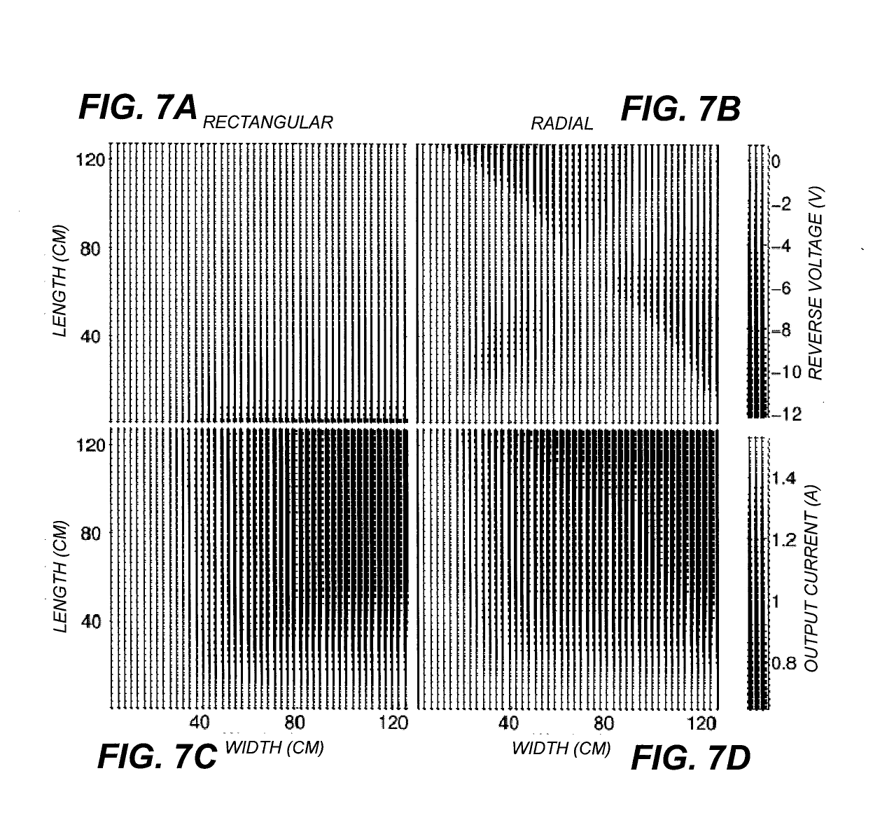

FIG. 6 is a plan view of thin film photovoltaic panel 600 according to various aspects (for clarity, not all cells are labeled). In panel 600, the shapes of cells 605 are selected to mitigate negative effects of shadows. Panel 600 includes a first plurality 610 of photovoltaic cells 605, 606B, here, the upper-left half (above the line from electrode 601 to electrode 607). Everything herein about cells 605 also applies to cell 606B. Cells 605 are electrically connected in series to each other, and are and arranged in a radial pattern. This radial pattern advantageously reduces the probability that a small number of cells will be shaded by a straight-edged shadow and a large number of cells will not be shaded by that shadow. Therefore, panel 600 can be less susceptible to shadow-induced damage than panel 200 (FIG. 2).

In this example, cells 605 are triangular in shape. In first plurality 610, each cell 605 has a slightly different shape than at least one other cell 605 since panel 600 as a whole is rectangular. Shadow 699 is shown falling on cells 605 in first plurality 610. Since each cell 605 is only slightly shaded, each cell continues to produce power as a whole, and the current passing through shaded areas is reduced. This mitigates reverse-bias-induced damage.

In various aspects, such as that shown, panel 600 further includes second plurality 620 of photovoltaic cells 605, 603, 604, 606A connected in series and arranged in a radial pattern (bottom-right corner). Everything herein relating to cells 605 also applies to cells 603, 604, 606A. First plurality 610 and second plurality 620 are electrically connected in parallel. In various aspects, output electrodes 601, 607 are disposed at diagonally-opposite corners of panel 600. Each of first plurality 610 and second plurality 620 is electrically connected to each of the output electrodes 601, 607. In various aspects, current generated by both first plurality 610 and second plurality 620 flows to a selected one of the electrodes 601, 607 (in this example, current flows to +electrode 607). In various aspects, the panel has groups of cells on two halves, and current flows clockwise in one half (e.g., first plurality 610) and counterclockwise in the other (e.g., second plurality 620). This is represented graphically by the dashed arrows. In various aspects, first plurality 610 includes the same number of photovoltaic cells 605 as second plurality 620. In various aspects, electrodes 601, 607 can be arranged horizontally, vertically, in the centers of edges or parallel to edges, or in other configurations.

Cell 606A, shown hatched, has a base of 2 L and a height of W/2, as shown. These dimensions correspond to dimensions W×L of a rectangular cell 105, e.g., as shown in FIG. 2. As a result, cells 606A and 606B together have the same area as one cell 105 (FIG. 2). Therefore, when the size of panel 600 is the same as the size of panel 200, panel 600 has largely the same output power and current as panel 200. Roughly the same area is illuminated, and the same number of cells are in series in each plurality 610, 620, which are themselves electrically parallel.

Various cell shapes can be used in panels according to various aspects. In some aspects, at least one of the cells is not aligned with, e.g., does not have an edge or a long axis aligned with an edge or long axis of, another one of the cells (e.g., cells 603, 604). In various aspects, cells 605 in first plurality 610 and second plurality 620 are arranged in a radially symmetric arrangement, and each cell 605 is triangular in shape. The term “radially symmetric” as used herein includes arrangements that are radially symmetric up to the point at which they are truncated at the perimeter of panel 600. In various aspects, panel 600 is rectangular, square, a parallelogram, or a circle.

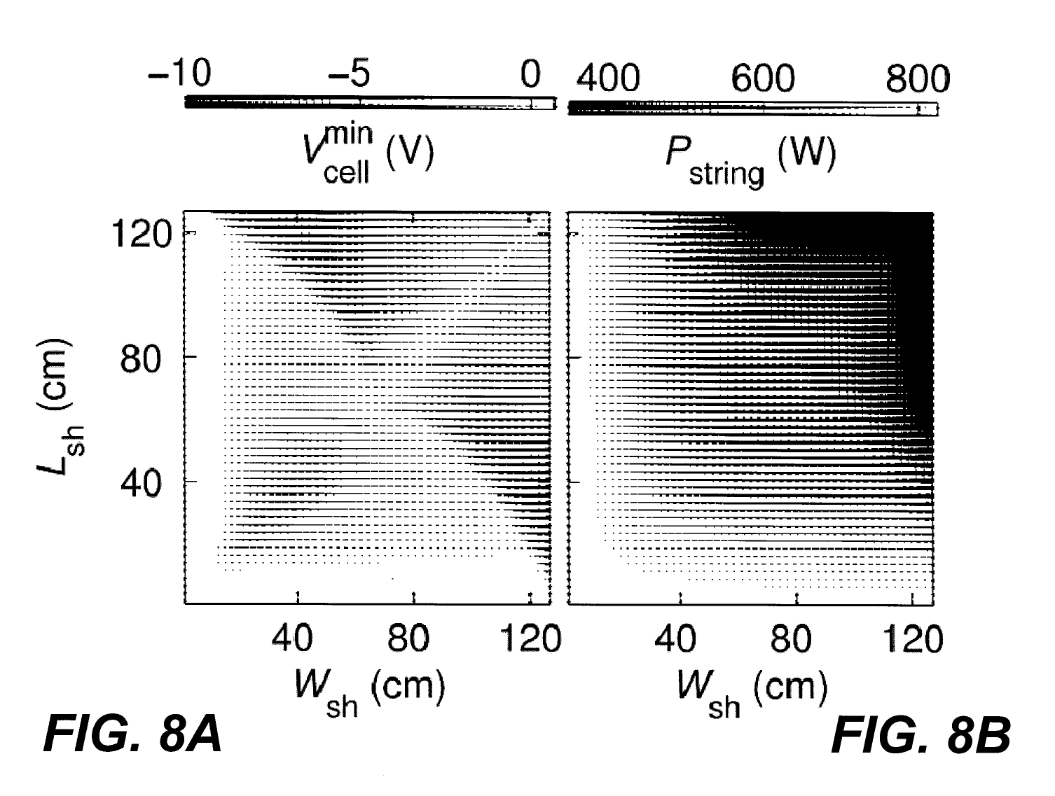

FIGS. 7A-7D show the results of simulations comparing panel 200 to panel 600. The axes of each plot are width and length of the shadow in centimeters. SPICE simulations of the panel configurations of FIG. 2 and FIG. 6 were performed. The SPICE model of panel 200 was two-dimensional, with each cell being modeled as a number of subcells. To simulate panel 600 under shade, a rectangular shadow of a particular size on panel 600 was mathematically transformed to obtain an equivalent shadow on panel 200. Panel 200 was then simulated with the transformed shadow.

FIGS. 7A and 7B show minimum cell voltage on the shaded panel (i.e., worst reverse bias); FIGS. 7C and 7D show panel power output. FIGS. 7A and 7C correspond to panel 200 (FIG. 2); FIGS. 7B and 7D correspond to panel 600 (FIG. 6). A legend for FIGS. 7A and 7B is provided to the right of FIG. 7B, and likewise right of FIG. 7D for FIGS. 7A, 7D.

FIGS. 7A and 7B clearly show that panel 600 has superior reverse-bias behaviour to panel 200 over much of the range of possible shadow sizes, and specifically that cells on panel 600 does not experience significant reverse breakdown for wide, short shadows (Wₛₕ>>Lₛₕ) that cause reverse bias of cells on panel 200. Note that in FIG. 7A, the lower-right corner (large Wₛₕ, small Lₛₕ) has strongly negative values, but that is not the case in FIG. 7B. FIGS. 7C and 7D also show that panel 600 produces more output power than panel 200 over an appreciable range of shadow sizes.

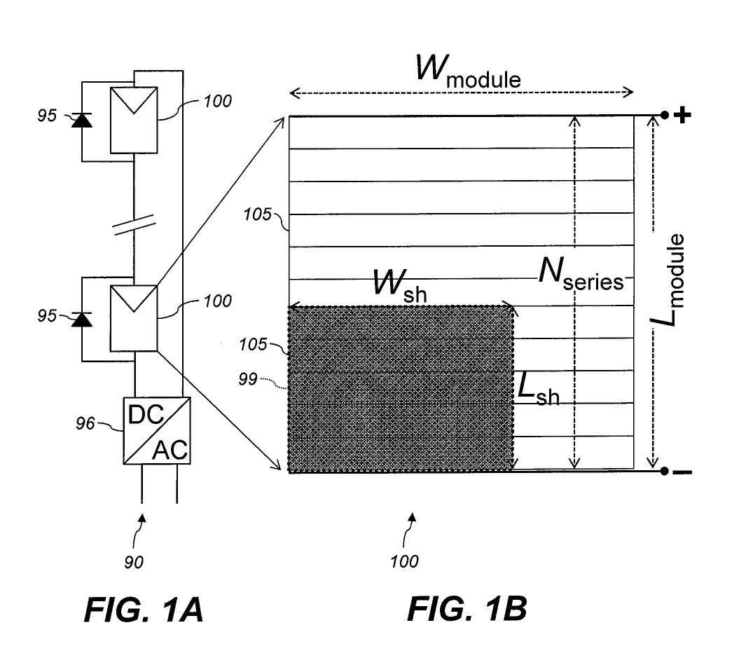

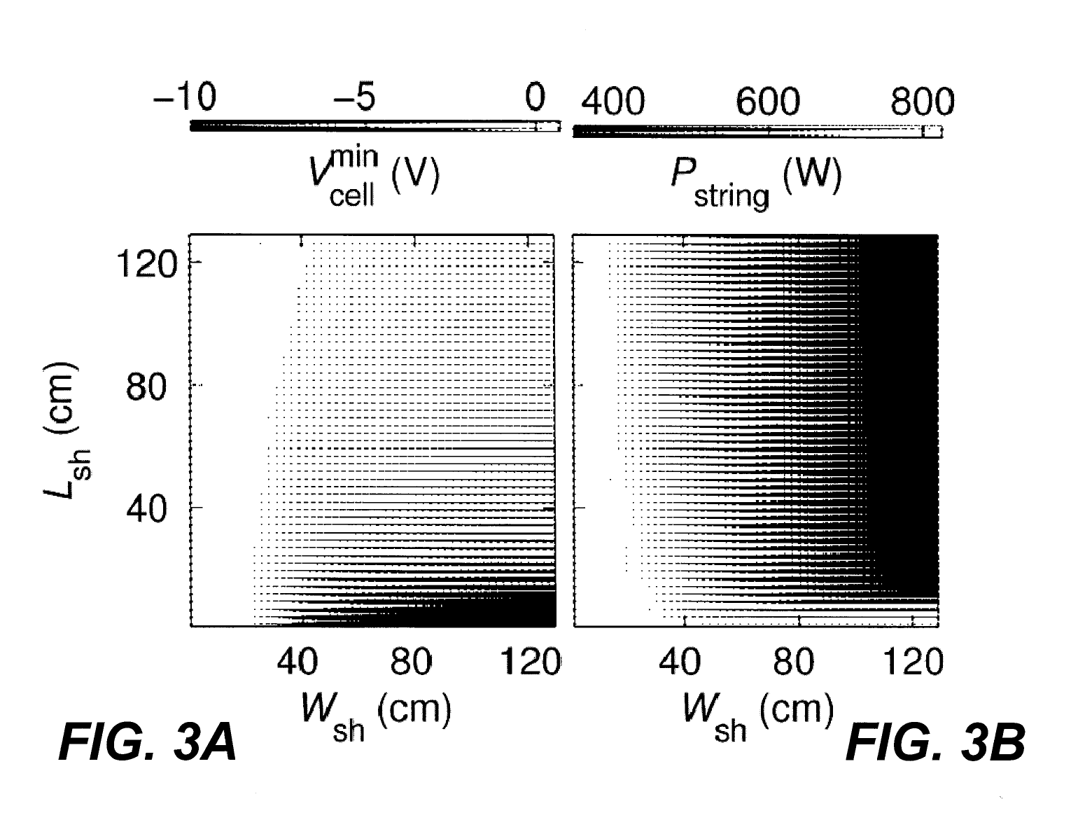

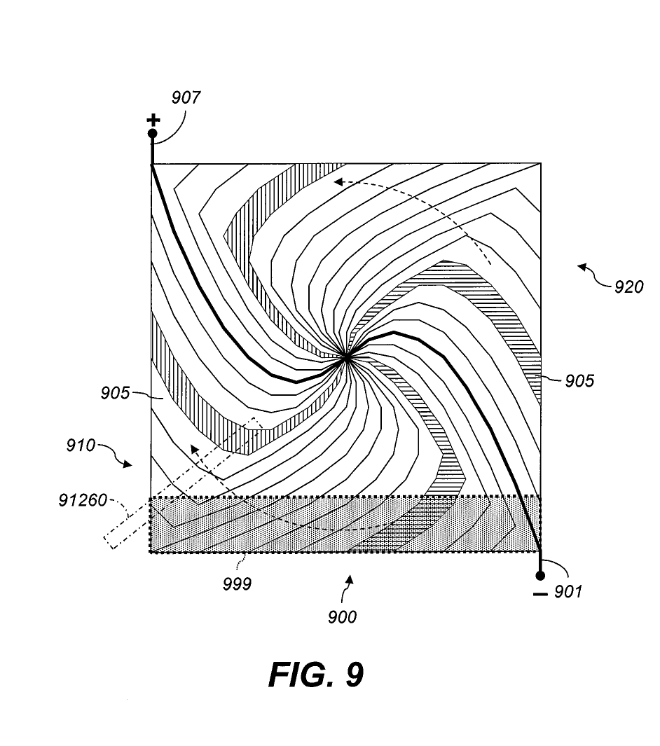

FIGS. 8A and 8B show results of further simulations of a radially-symmetric triangular-cell panel such as panel 600 (FIG. 6). These simulations were performed using a 1-D equivalent circuit similar to that described above with reference to FIGS. 3A-3B. FIG. 8A shows most-negative reverse bias and FIG. 8B shows output power for a string of panels similar to that shown in FIG. 1A. FIG. 8A shows that most-negative (worst case) reverse bias is now around −4.7V, much improved compared to the −10V or below of panel 200 (FIG. 2). FIG. 8A also shows that Wₛₕ>>Lₛₕ shadows (lower-right corner) and Wₛₕ<<Lₛₕ shadows (upper-left corner) behave similarly. Therefore, this design has improved robustness against shadow orientation compared to panel 200. FIG. 8B shows that output power for this panel design lowers gracefully rather than sharply as a shadow covers the panel.

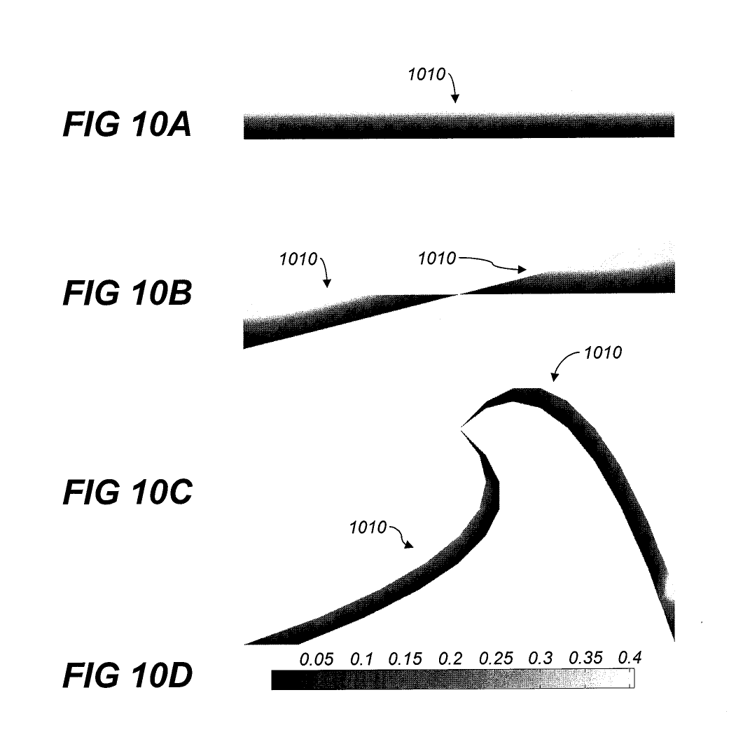

FIG. 9 shows a top view of TFPV panel 900 according to various aspects, and partly shaded by shadow 999 (dotted outline). In the example shown, panel 900 has cells 905 arranged in a radially-symmetrical spiral pattern (truncated to the rectangular shape of panel 900). In various aspects, a TFPV panel has first plurality 910 of photovoltaic cells 905 electrically connected in series between electrodes 901, 907. The cells in series are referred to as “chains.” Each cell 905 is adapted to produce a respective current substantially equal to a selected first chain current under a selected illumination condition. For example, the currents in each cell in a given chain between electrodes 901, 907 are substantially the same as each other.

Cells 905 are shaped and arranged so that any straight-edged shadow falling on the panel at least partly shades two cells. Such a shadow, e.g., shadow 999, can shade any number of cells, but since at least two are shaded, it will not be the case that a single cell is shaded by a straight-edged shadow and is thus driven into reverse bias by all the other cells combined. As used herein, the term “straight-edged shadow” is a shadow with at least one edge that is substantially a straight line. That edge can be sharp or blurry. Such a shadow can extend perpendicular to that straight edge by any amount at least one wavelength of light being shaded (e.g., >=300 nm if the shadow is blocking CIE D65 light). Any shadow having the straight edge intersecting two or more sides of the panel, or intersecting the perimeter of the panel in two or more different cells, is considered to be falling on the panel.

Similarly to discussion above with reference to FIG. 6, panel 900 can include including second plurality 920 of photovoltaic cells 905 connected in series. First plurality 910 and second plurality 920 can be electrically connected in parallel. Cells 905 in the first and second pluralities 910, 920 can be arranged in a radially symmetric arrangement. Thin film photovoltaic panel 910 can be rectangular or another shape. Output electrodes 930, 940 can be disposed at diagonally-opposite corners of panel 900, and first plurality 910 and second plurality 920 can each be electrically connected to each of the output electrodes 901, 907. Current generated by first plurality 910 and current generated by second plurality 920 can flow to a selected one of the electrodes 901, 907 (one half clockwise, one half counterclockwise), as indicated by the dashed arrows. Cells 905 can be arranged in a radial pattern.

In various aspects, each cell 905 has a bent shape. Bent shapes can include hockey-stick shapes, spirals, Bezier curves, and other plane curves that are substantially not line segments. The scribe lines between cells 905 can have shapes of any of these types. A scribe lines can include a plurality of connected line segments. In various aspects, each cell 905 has a concave polygonal shape. Cells 905 on a single panel can be in various combinations, e.g., some convex and some concave.

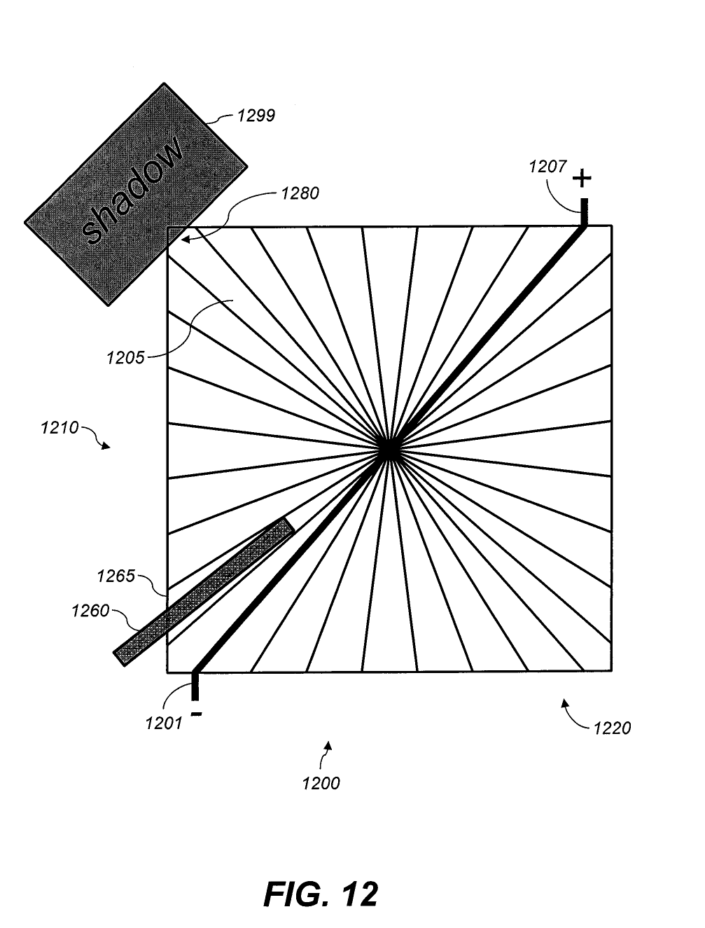

FIGS. 11A and 11B show results of simulations of a radially-symmetrical spiral panel similar to panel 900 (FIG. 9). The axes are as FIGS. 3A and 3B; a legend is provided above each figure. As can be seen, panel 900 has substantially improved properties compared to panel 200 (FIG. 2). The worst-case reverse-bias from shading in this spiral design is limited to −4.2V, and the overall number of cases which result in reverse bias is also reduced compared to panel 200. Due to the curved cell shape, the asymmetric shading problem does not arise for rectilinear shadows.

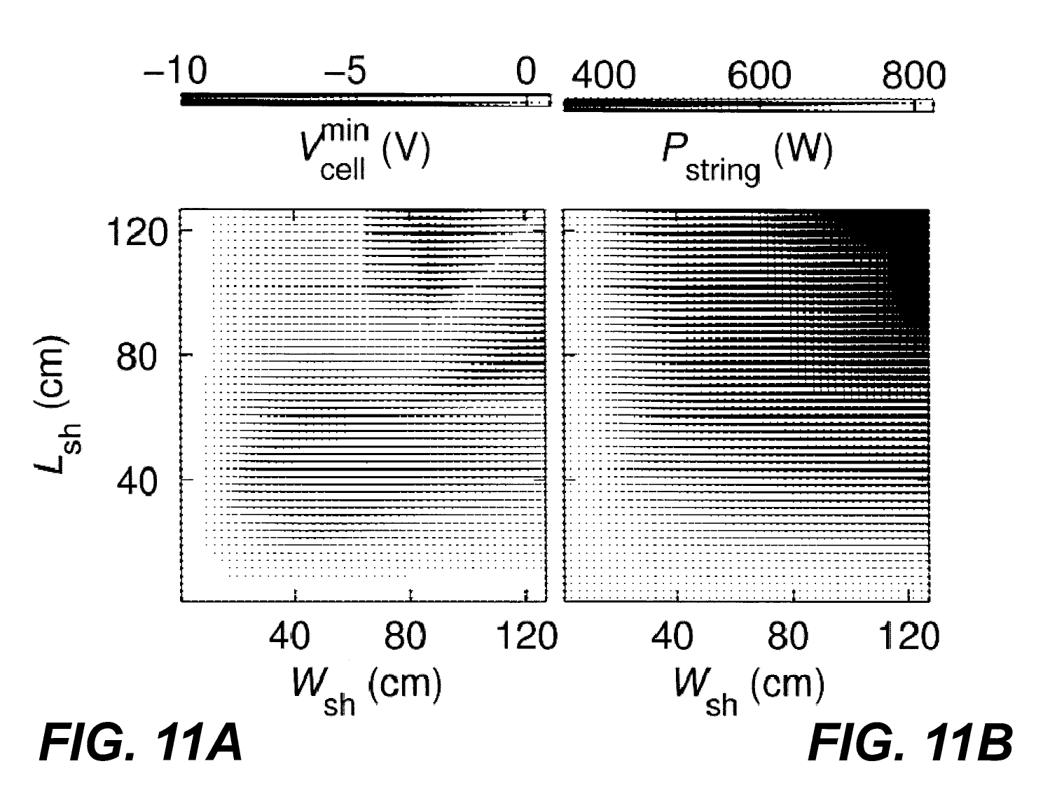

FIGS. 10A-10C shows results of simulations of resistive power dissipation in in contact layers of fully illuminated cells of various shapes: panel 200, panel 600, and panel 900, respectively. These simulations represent normal operation conditions. FIG. 10D shows a common legend for FIGS. 10A-10C. In all three figures, current flows to the left and up. As shown, panel 900 (FIG. 10C), with spiral cells, has lower resistive power dissipation at current-collecting edges 1010 (top and left edges) than does panel 600. Both panel designs are useful and can provide improvements compared to prior schemes. Spiral designs such as panel 900 provide a further advantage of reduced power dissipation because of the increased ratio between the length of the current-collecting edge 1010 for a cell and the area of that cell.

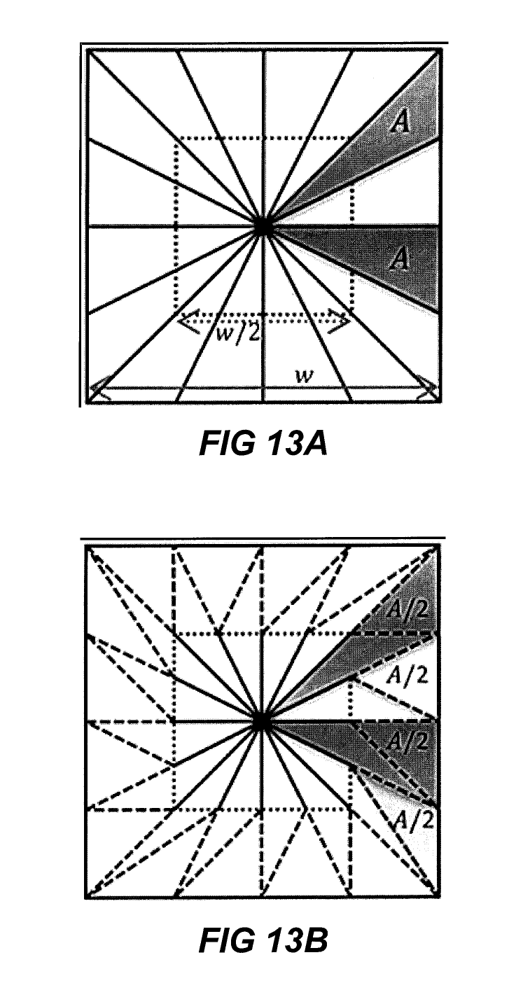

FIG. 12 shows TFPV panel 1200 according to various aspects. First plurality 1210 and second plurality 1220 have cells 1205 as described above with reference to FIG. 6 (see pluralities 610, 620). Electrodes 1201, 1207 are not in the corners, so corner 1280 is entirely occupied by only one cell 1205. Straight-edged shadow 1299 does fall on panel 1200 since it intersects the top side and the left side, as discussed above. However, shadow 1299 covers so little of panel 1200 that it only at least partly shades one cell: cell 1205. In this and other aspects, a shadow shading at least 1% of the panel is considered to be falling on the panel, and the cells are shaped and arranged so that a shadow falling on the panel will at least partly shade two cells. In various of these aspects, the cells are shaped and arranged so that a shadow that shades less than one percent of the panel will shade less than 50% of the area of a single cell, e.g., as shown here. In various aspects, the cells are shaped and arranged so that a straight-edged shadow that at least partly shades only one cell shades at most 50% of that cell. In some aspects, triangular cells are use and are arranged so that each pair of triangles has the same area as a single rectangle in a reference configuration, e.g., as discussed above with reference to FIG. 6. In some of these aspects, the cells are shaped and arranged so that a straight-edged shadow that at least partly shades only one cell shades at most 25% of the combined area of two cells that together have the same area as a corresponding rectangular cell (e.g., cell 105, FIG. 2).

In various aspects, the panel includes a plurality of cells shaped and arranged so that the area overlap between straight edge shadow and cell areas is distributed in a largely symmetric manner. Significant asymmetry in shaded areas of cells, e.g., 1-5 cells shaded more than 50%, and the rest shaded less than 5-10%, is thus avoided. In various aspects, the cells are shaped so that a single cell cannot be shaded fully by a straight edge shadow.

Shadow 1260 represents a shadow that can cause damage to cell 1265. Everything discussed about cells 1205 also applies to cell 1265. Shadow 1260 is not considered to fall on panel 1200, as discussed above, since it neither intersects two or more sides of the panel nor intersects the perimeter of the panel in two or more different cells (it intersects the perimeter entirely in cell 1265). No matter the configuration of cells, there will always be some shadow to which a particular panel is vulnerable. However, inventive panels such as panel 1200, shown here, and panels 600 and 900 (FIGS. 6, 9 respectively) are much less vulnerable to typical shadows than comparative panel 200. Moreover, panel 900 would not be vulnerable to shadow 1260. Referring back to FIG. 9, shadow 91260 (dash-dot outline) shows where shadow 1260 would fall on panel 900. As can be seen, shadow 91260 does intersect the perimeter of panel 900 in at least two cells, so it is considered to be falling on panel 900. However, shadow 91260 does not obscure a significant portion of any of the six cells it partially obscures. This demonstrates that panel 900 is not vulnerable to shadow 91260. The arrangement of cells on a panel can be selected based on objects around the location where the panel is likely to be installed. Shadows falling across the area that is to hold the panel can be photographed and analyzed, and cells can be shaped substantially different from those shadows.

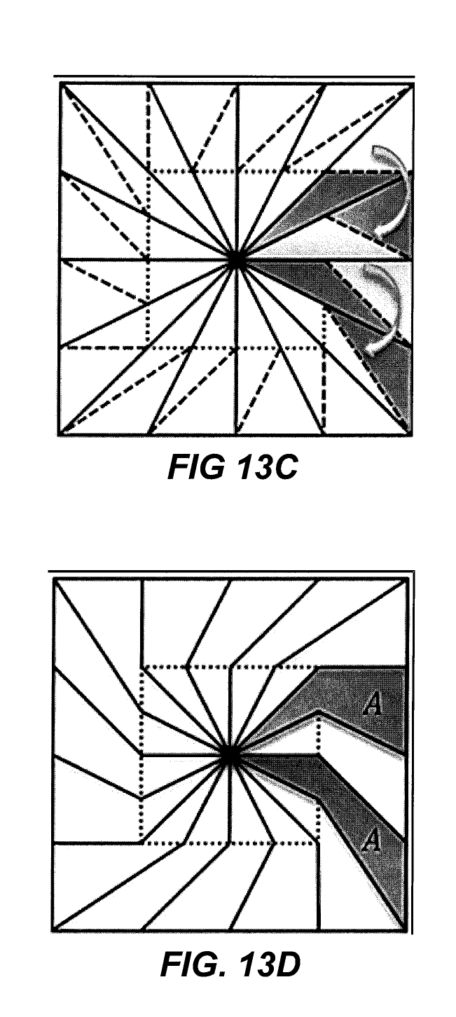

FIGS. 13A-13D show steps in designing a spiral geometry for a TFPV panel. This design preserves the series connection between cells and the rectangular module geometry. FIGS. 13A-13D show a step by step schematic representation of a design step. This design step is repeated recursively multiple times to design a selected spiral geometry.

FIG. 13A shows radial geometry with triangular half-cells of equal area, inside a square module of side w. The dotted square of side w/2 contains the same radial pattern with half-cell area A/4. FIG. 13B shows the triangles divided into two parts with equal areas A/2 along the dashed lines. All the triangles at the outer edges are of equal areas. Therefore, in the next step, shown in FIG. 13C, the triangles are exchanged in a clockwise fashion, without distorting the overall square module shape. Finally, as shown in FIG. 13D, the rotated shapes are merged to create concave irregular pentagons with the same area A as the initial triangles. This results in the required twisted module geometry, with one level of bending at w/2. In order to create a more curved polygonal cell, the process of FIGS. 13A-13D is iterated, so that the geometry is twisted at more points a distance w/N apart. Once all geometric manipulation has been performed, the panel can be scribed to separate the resulting polygons.

The invention is inclusive of combinations of the aspects described herein. References to “a particular aspect” and the like refer to features that are present in at least one aspect of the invention. Separate references to “an aspect” or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A thin film photovoltaic panel comprising a first plurality of photovoltaic cells electrically connected in series and arranged in a radial pattern.

2. The thin film photovoltaic panel according to claim 1, further including a second plurality of photovoltaic cells connected in series and arranged in a radial pattern, the first and second pluralities electrically connected in parallel.

3. The thin film photovoltaic panel according to claim 2, wherein the cells in the first and second pluralities are arranged in a radially symmetric arrangement.

4. The thin film photovoltaic panel according to claim 3, wherein each of the cells is triangular in shape.

5. The thin film photovoltaic panel according to claim 2, wherein the thin film photovoltaic panel is rectangular.

6. The thin film photovoltaic panel according to claim 5, further including two output electrodes disposed at diagonally-opposite corners of the thin film photovoltaic panel, so that each of the first plurality and the second plurality is electrically connected to each of the output electrodes.

7. The thin film photovoltaic panel according to claim 6, wherein current generated by both the first plurality and the second plurality flows to a selected one of the electrodes.

8. A thin film photovoltaic panel comprising a first plurality of photovoltaic cells electrically connected in series, each of the cells adapted to produce a respective current substantially equal to a selected first chain current under a selected illumination condition, wherein the cells are shaped and arranged so that any straight-edged shadow falling on the panel at least partly shades two cells.

9. The thin film photovoltaic panel according to claim 8, wherein each of the cells has a bent shape.

10. The thin film photovoltaic panel according to claim 8, further including a second plurality of photovoltaic cells connected in series, the first and second pluralities electrically connected in parallel.

11. The thin film photovoltaic panel according to claim 10, wherein the cells in the first and second pluralities are arranged in a radially symmetric arrangement.

12. The thin film photovoltaic panel according to claim 10, wherein the thin film photovoltaic panel is rectangular.

13. The thin film photovoltaic panel according to claim 12, further including two output electrodes disposed at diagonally-opposite corners of the thin film photovoltaic panel, so that each of the first plurality and the second plurality is electrically connected to each of the output electrodes.

14. The thin film photovoltaic panel according to claim 13, wherein current generated by both the first plurality and the second plurality flows to a selected one of the electrodes.

15. The thin film photovoltaic panel according to claim 10, wherein the first plurality includes the same number of photovoltaic cells as the second plurality.

16. The thin film photovoltaic panel according to claim 8, wherein each of the cells is arranged in a radial pattern.

17. The thin film photovoltaic panel according to claim 8, wherein each of the cells has a concave polygonal shape.

18. The thin film photovoltaic panel according to claim 8, wherein the cells are shaped and arranged so that any straight-edged shadow shading at least 1% of the panel at least partly shades two cells.
